(19) United States
(12) Patent Application Publication
(10) Pub. No.: US 2020/0124654 A1
(43) Pub. Date: Apr. 23, 2020

(54) INSTRUMENT FOR TESTING TERMINAL CONNECTORS

(71) Applicant: Sumitomo Wiring Systems, Ltd., Yokkaichi (JP)

(72) Inventors: Brian D. Carnick, Farmington Hills, MI (US); Gregory A. Gabriele, Farmington Hills, MI (US)

(21) Appl. No.: 16/165,097

(22) Filed: Oct. 19, 2018

(51) Int. Cl. G01R 31/04; G01R 1/073; G01R 1/067

(52) U.S. Cl. CPC G01R 31/045; G01R 1/06722; G01R 1/06738; G01R 1/07307

(57) ABSTRACT

An instrument for testing the electric connection of a male terminal connector is provided. The instrument includes a female connector housing having a female board with a plurality of terminal cavities and a plurality of biasing contacts. The biasing contacts are configured to move between a first position and a second position. In the second position the head is depressed relative to the first position. Thus, the head is configured to engage a distal end of the male terminal blade so as to provide an electric connection. Further, the head is configured to give way to a misaligned male terminal blade. Accordingly, the instrument will maintain a predetermined surface contact with the male terminal blades and allow for misalignment of the male terminal blade with respect to the terminal cavity so as to reduce the occurrence of a faulty defect reading.

### TECHNICAL FIELD

The present specification generally relates to instruments for testing connector assemblies, and more particularly to eliminate faulty defect readings.

### BACKGROUND

Terminal connectors are housed in a male and female connector housing. The terminal connectors include a male terminal connector configured to couple with a female terminal connector so as to complete an electric connection. An illustrative view of a male connector housing 400 is shown in FIGS. 1 and 2. The male connector housings 400 are configured to distribute and/or regulate power to various electronic devices. The connector housings are tested prior to installation in a device, such as an automotive vehicle. Accordingly, it is known to use testing equipment configured to resemble female housing with female terminal connectors to test male connectors with male terminal connectors and vice-versa.

In one embodiment, the male connector housing 400 is a power circuit board. The male connector housing 400 includes terminal cavities 410 which accommodate the male terminal connectors 420. The male terminal connectors 420 include a male terminal blade 430 and a wire 440 coupled to the male terminal blade 430. The wires 440 connect the male terminal blades 430 to a respective electronic device or circuit, such as a fuse, relay or the like (not shown). Prior to distribution, the male connector housings 400 are tested to ensure that the electric connection between the male terminal connectors 420 and the electronic devices meet certain specifications.

FIGS. 1 and 2 depict an embodiment of an instrument 500 currently used for testing the electric connection of a male terminal connector housing 400. As shown the instrument 500 is a female connector housing 510. The female connector housing 510 includes a plurality of terminal cavities 520 formed on a female board 530. Each of the terminal cavities 520 includes a female connector 540 (shown in FIG. 2). The female connector 540 includes a pair of resilient prongs 540a, 540b spaced apart from each other so as to receive a male terminal blade 430. The female connector 540 further includes a wire 550 electrically coupled to a processing unit 560. The processing unit 560 is configured to detect the electric signal from each of the male terminal connectors 420.

The processing unit 560 includes an executable program 580 configured to read the electric connection between the male connector housing 400 and the female connector housing 510. Thus, a poor coupling between respective male and female terminal connectors 420, 540 may result in a determination that the male terminal connectors 420 are deficient, even when they are not.

The prongs 540a, 540b of the female connectors 540 may become stretched over time as a result of numerous testing. For instance, each time a male terminal blade 430 is inserted into a female connector 540 the prongs 540a, 540b are displaced away from each other. This may reduce the biased engagement of the prongs 540a, 540b onto the male terminal blades 430.

FIG. 2 shows a depiction of prongs 540a, 540b (shown on the far right) spaced further apart from each other as a result of excessive reception of a male terminal blade 430. The reduction in a biased engagement may result in a poor electric connection, which is not attributable to the condition of the male terminal blade 430. Also stated, the current testing instrument provides a faulty defect reading in such a scenario.

In addition to, or in the alternative, a male terminal blade 430 may be introduced into a respective female terminal cavity 520 in a misaligned direction which causes the male terminal blade 430 to be pressed against a top surface of a prong 540a as shown on the left and middle figure. Such a misalignment may cause one of the prongs 540a to bend and deform so as to be spaced further apart from the other prong relative to its first state. Such a deformation may result in a poor electric connection, which is not attributable to the condition of the male terminal connector but rather the deformation of the prongs 540a, 540b. Also stated, the current testing instrument provides a faulty defect reading in such a scenario. Additionally, the force exerted onto a male terminal blade 430 due to a misalignment of prongs 540a, 540b may cause the male terminal blade 430 to bend, as shown in the left and center prongs 540 shown in FIG. 2.

Accordingly, it remains desirable to have an instrument configured to test a male connector housing that will maintain a predetermined surface contact with the male terminal blades and allow for misalignment of the male terminal blade with respect to the terminal cavity so as to reduce the occurrence of a faulty defect reading.

### SUMMARY

An instrument for testing the electric connection of a terminal connector is provided. The instrument includes a connector housing having a board with a plurality of terminal cavities. The instrument further includes a plurality of biasing contacts. The biasing contacts are disposed beneath and axially aligned to a respective terminal cavity. The biasing contacts are configured to move between a first position and a second position, wherein in the second position a top surface of the biasing contact is depressed relative to the first position. Accordingly, the testing equipment utilizes a contact between the biasing contact and the terminal connector to establish an electrical connection.

In one embodiment, the instrument is configured to test a male connector housing with a male terminal connector. The instrument includes a female connector housing having a female board with a plurality of terminal cavities. The instrument further includes a plurality of biasing contacts. The biasing contacts are disposed beneath and axially aligned to a respective terminal cavity. The biasing contacts are configured to move between a first position and a second position, wherein in the second position a top surface of the biasing contact is depressed relative to the first position.

Each of the biasing contacts includes a testing wire. The testing wires are electrically coupled to a processing unit. The processing unit includes an executable program configured to read the electric connection between the male connector housing and the female connector housing. In particular, the executable program is configured to read the electric connection between each of the male terminal blades and a respective biasing contact.

The biasing contact includes a base and a head. The head is configured to be axially displaced relative to the base. The biasing contact is configured to move between a first position and a second position, wherein in the first position the head is extended upwardly and in the second position the head is depressed relative to the first position. In other words, the head may be pressed down into the second position by a male terminal blade and move up to the first position when the male terminal blade is removed from the instrument. Thus, the head is configured to engage a distal end of the male terminal blade so as to provide an electric connection between the instrument and the male connector housing. Further, the head is configured to give way to a misaligned male terminal blade.

In one embodiment, the biasing contact includes a biasing member housed within the base. The biasing member may be a helical spring. The helical spring is configured to continuously urge the head into the first position.

In one embodiment, the head includes a plurality of teeth spaced apart from each other so as to receive a distal edge of the male terminal blade between adjacent teeth. The teeth may be formed as a single unit with the head through a stamping process.

Accordingly, an instrument configured to test a connector housing is provided that will maintain a predetermined surface contact with the terminal blades and allow for misalignment of the terminal blade with respect to the terminal cavity so as to reduce the occurrence of a faulty defect reading.

### BRIEF DESCRIPTION OF THE DRAWINGS

The embodiments set forth in the drawings are illustrative and exemplary in nature and not intended to limit the subject matter defined by the claims. The following description of the illustrative embodiments can be understood when read in conjunction with the following drawings, where like structure is indicated with like reference numerals and in which:

FIG. 1 schematically depicts a connector housing of the prior art;

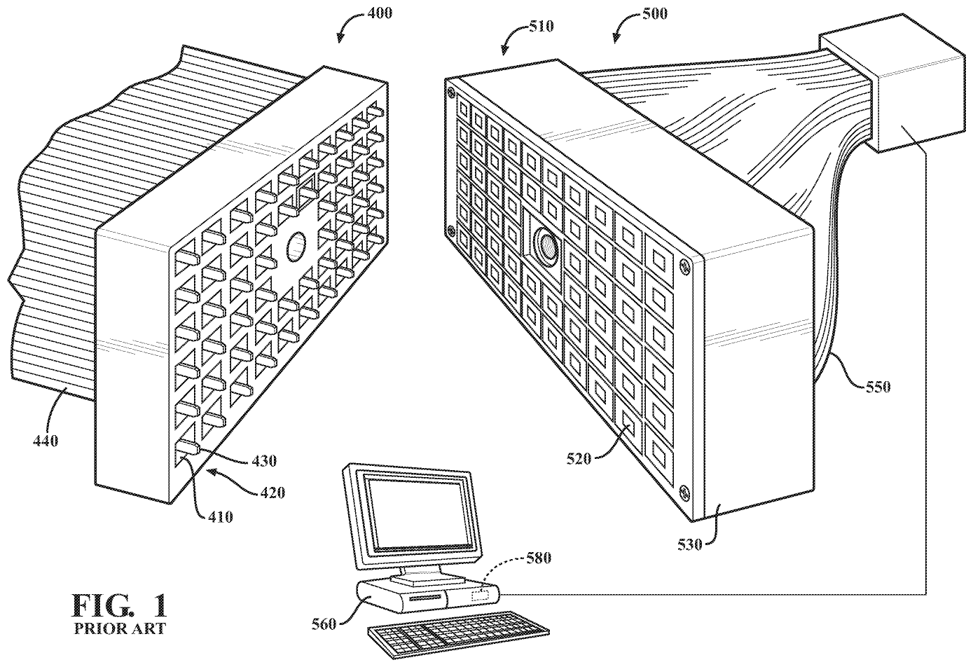

FIG. 2 is a cross-sectional view taken from the front of the male connector housing shown in FIG. 1;

FIG. 3 schematically depicts an instrument according to one or more embodiments described and illustrated herein;

FIG. 4A is a cross-sectional view of the instrument shown in FIG. 3 showing the biasing contacts in a first position;

FIG. 4B is a view of FIG. 4A showing the biasing contacts in a second position; and

FIG. 5 is a view showing the instrument housing with the board removed.

### DETAILED DESCRIPTION

Referring generally to the figures, embodiments of the present disclosure directed towards an instrument for testing the electric connection of a terminal connector and reducing a faulty defect reading are provided.

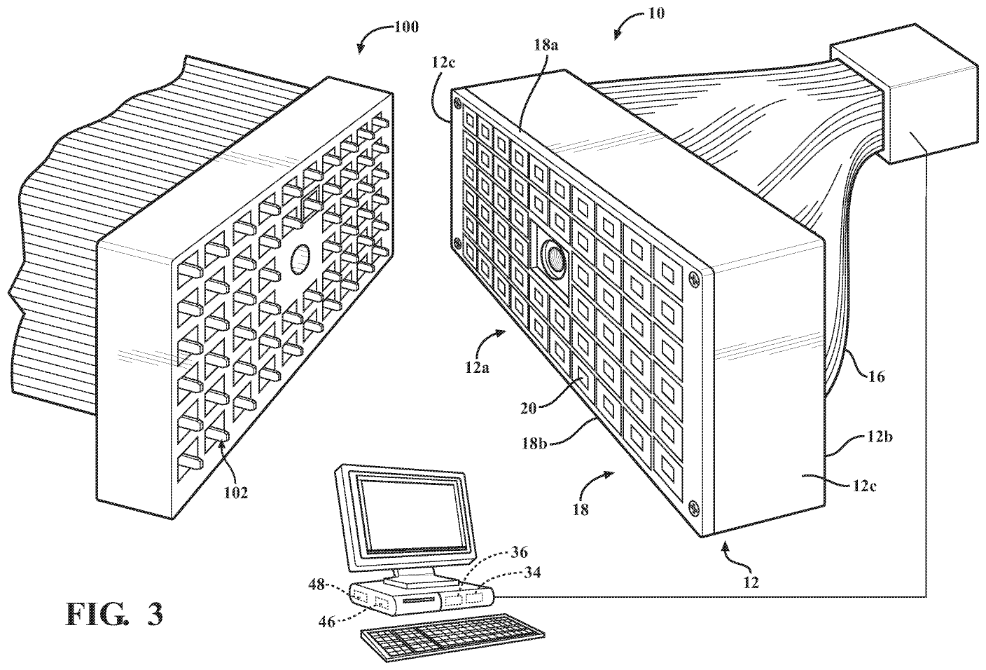

Referring to FIGS. 3-5, the instrument 10 includes a first connector housing 12 having a board 18 with a plurality of terminal cavities 20 which may be oriented in a plurality of rows 22 each row 22 having a predetermined number of terminal cavities 20. The instrument 10 is configured to test a second connector housing 100 having a plurality of terminal connectors 102.

The instrument 10 further includes a plurality of biasing contacts 24. The biasing contacts 24 are disposed beneath and axially aligned to a respective terminal cavity 20. The biasing contacts 24 are configured to move between a first position and a second position, wherein in the second position a top surface of the biasing contact is depressed relative to the first position. Accordingly, the testing instrument 10 utilizes a contact between the biasing contacts 24 and the terminal connectors 102 of the second connector housing 100 which are to be tested to establish an electrical connection.

As used herein the terms front, back, top and bottom are made in reference to the orientation of instrument 10 shown in FIG. 3. The terms up and down refer to the movement of the related part in reference to the terms top and bottom.

For illustrative purposes, a description of the embodiments of an instrument 10 for testing a terminal connector 102 will be made with reference to an instrument having a female connector housing configuration so as to test a male connector housing. However, it should be appreciated that the embodiments described herein are not limiting to just a female connector housing configuration.

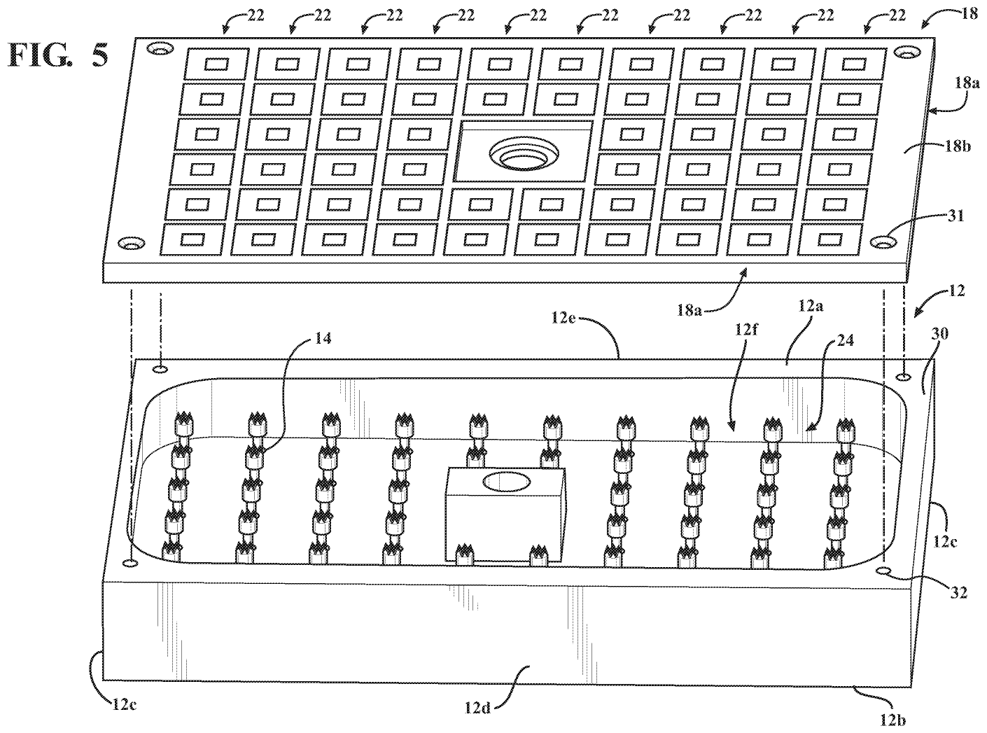

With reference now to FIGS. 3 and 5, an illustrative depiction of an instrument 10 for testing the electric connection of a male connector housing 100 is provided. The male connector housing 100 is illustratively shown as a power circuit board. The instrument 10 includes a female connector housing 12. The female connector housing 12 may be formed as a single unit made by an injection mold process. The female connector housing 12 includes a front wall 12a, a back wall 12b, a pair of side walls 12c, a bottom wall 12d and a top wall 12e. The side walls 12c, bottom wall 12d and top wall 12e are generally orthogonal to the back wall 12b and define a storage compartment 12f. The back wall 12b includes a plurality of wire openings 14 configured to receive a portion of a testing wire 16.

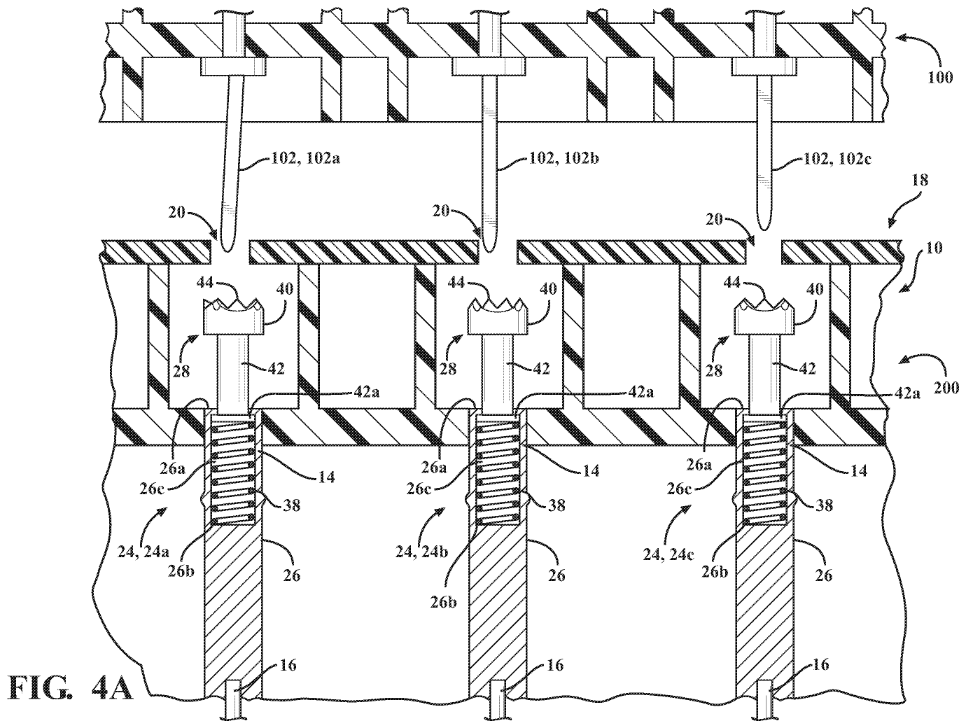

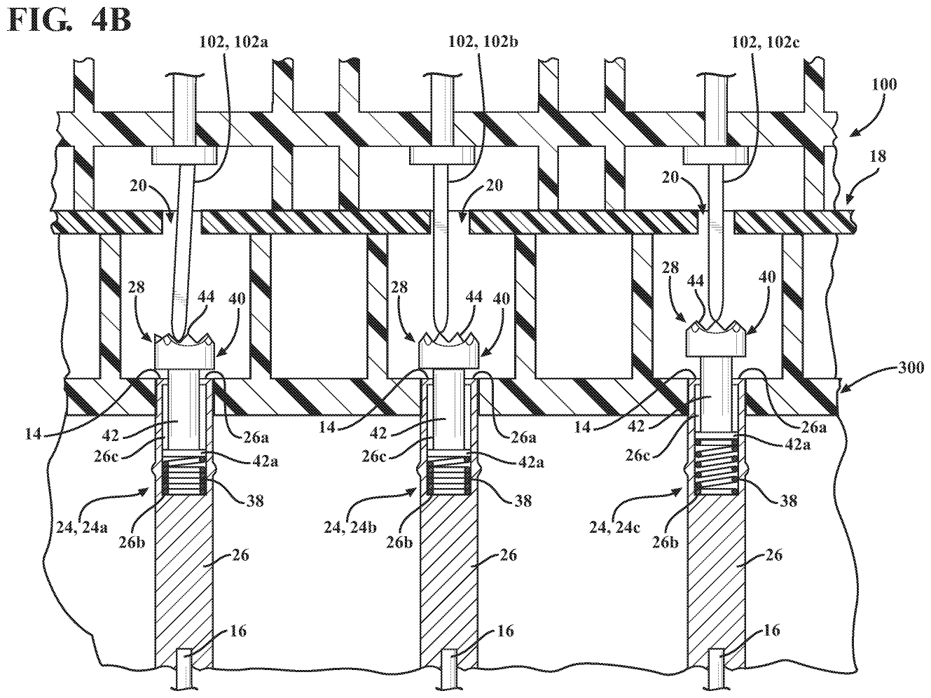

The instrument 10 includes a female board 18 which covers the storage compartment 12f of the female connector housing 12. The female board 18 includes a plurality of terminal cavities 20. The female board 18 is configured to mount onto the storage opening 12f of the female connector housing 12. The female board 18 is a generally planar member with a peripheral wall 18a bounding a top surface 18b of the female board 18. The terminal cavities 20 are illustratively shown as rectangular openings and are dimensioned to receive a male terminal blade 102 of a male terminal connector housing 100. Each of the terminal cavities 20 is axially aligned with a respective wire opening 14 (as shown in FIGS. 4A and 4B).

The female board 18 may be configured to engage the female connector housing 12 using known engagement means. For instance, the female board 18 may include a resilient tab configured to engage a corresponding indent of the female connector housing 12 in a snap fit engagement. Alternatively, a fastener, such as a threaded bolt may be used to couple the female board 18 to the female connector housing 12.

The female board 18 may include a plurality of rows 22, with each row 22 having a predetermined number of terminal cavities 20. For illustrative purposes, the female board 18 includes ten (10) rows 22. As shown, most of the rows 22 have six (6) terminal cavities 20 wherein the rows in the center of the female board have four (4) terminal cavities to accommodate space for a fastening structure. The female board 18 illustratively shown herein includes a total of fifty-six (56) terminal cavities 20. Likewise, the back wall 12b (shown in FIG. 5) of the female connector housing 12 includes fifty-six (56) wire openings 14, each wire opening 14 is axially aligned to a corresponding terminal cavity 20. The instrument 10 further includes fifty-six (56) wires 16 (illustratively shown in FIGS. 4a and 4b) protruding from respective wire openings 14. It should be appreciated that the number of terminal cavities 20 shown are not limiting to the scope of the appended claims.

With reference now to FIGS. 4A and 4B, the instrument 10 further includes a plurality of biasing contacts 24. The biasing contacts 24 are disposed beneath and axially aligned to a respective terminal cavity 20. The biasing contacts 24 are formed of an electric conductive material. The biasing contacts 24 are configured to engage and accommodate an axial displacement of a male terminal blade 102.

The biasing contact 24 includes a base 26 and a head 28. The head 28 is configured to be axially displaced relative to the base 26. The base 26 and the head 28 are both formed of an electric conductive material. The outer surface of the base 26 and the head 28 may be coated or sheathed by a protective material. However, the top surface of the head 28 is electrically conductive and at least an inner surface of the base 26 is electrically conductive. The testing wire 16 is electrically coupled to the base 26 such that an electric path is formed from the top surface of the head 28 to the testing wire 16.

The biasing contact 24 is configured to move between a first position 200 (shown in FIG. 4A) and a second position 300 (shown in FIG. 4B). In the first position 200 the head 28 is extended upwardly and in the second position 300 the head 28 is depressed relative to the first position 200 by engagement with a respective male terminal blade 102. As used herein, upwardly refers to the direction from the back wall 12b to the female board 18 when the female connector housing 12 is assembled, as shown in FIG. 3. Depressed refers to a displacement opposite upwardly. The biasing contact 24 is further configured to automatically return to the first position 200. Accordingly, the head 28 is configured to be depressed upon contact with a male terminal blade 102 inserted into the corresponding terminal cavity 20 of the female board 18.

In one embodiment, shown in FIG. 5, the board 18 is fastened to the female connector housing 12. A top surface 30 of the female connector housing 12 may include a plurality of apertures 32. In one embodiment, the apertures 32 are threaded. The board 18 includes apertures 31 registered to align with a corresponding aperture 32 so as to allow a fastener (not shown) such as a screw to secure the board 18 to the female connector housing 12 so as to close the storage compartment 12f.

With reference again to FIGS. 3, 4a and 4b, the wires 16 are coupled on one end to a respective base 26 of a biasing contact 24, and coupled to a processing unit 34 on the other end. The processing unit 34 may be embedded in a portable electronic device or a desktop. The instrument 10 may further include an electronic circuit 36 to modify the signal received from the male terminal connector 100 into a readable form. The processing unit 34 is configured to read the signal received by the female connector housing 12 from the male terminal connector housing 100 through each of the electrical connections, wherein the electrical connection is defined herein as a coupling of the male terminal blade 102 to the biasing contact 24.

In one embodiment, the biasing contact 24 includes a biasing member 38 housed within the base 26. The base 26 is generally a cylindrical member with an open end 26a opposite a closed end 26b and an elongated chamber 26c defined by a continuous wall. The biasing member 38 is seated against the closed end 26b within the elongated chamber 26c. A portion of the head 28 is disposed within the elongated chamber 26c and is continuously urged into the first position 200 by the biasing member 38. Any biasing member 38 currently known or later developed may be adapted for use herein, illustratively including a helical spring.

In one embodiment, the head 28 includes a contact portion 40 and a stem 42. The stem 42 is a generally cylindrical member configured to slidingly fit within the elongated chamber 26c. A bottom portion of the stem 42 may include a radial flange 42a. The open end 26a of the base 26 may include an annular rib, wherein the radial flange 42a is seated beneath the annular rib. The annular rib and the radial flange 42a work together to retain the stem 42 of the head 28 within the elongated chamber 26c.

In one embodiment, the head 28 includes a plurality of teeth 44 spaced apart from each other so as to receive a distal edge of the male terminal blade 102 between adjacent teeth 44. The teeth 44 may be formed as a single unit with the head 28 through a stamping process. The teeth 44 are illustratively shown as having a cross-section in the shape of an isosceles triangle, wherein the opposing sides of the teeth 44 are angled so as to guide the distal end of the male terminal blade 102 into the trough formed at the bottom between adjacent teeth 44. It should be appreciated that the shape of the head 28 may be modified without deviating from the scope of the appended claims. For instance, the teeth 44 may be rounded, alternatively the head 28 may include a dent for receiving the distal end of the male terminal blade 102, or the top surface of the head 28 may be flat.

It should be appreciated that the biasing contact 24 is configured to move from the first position to the second position using other mechanisms currently known and used in the art, illustratively including a fluid chamber with a compressed air system, or the biasing member may be disposed on the outer surface of the base and the stem 42 is operatively coupled to the biasing member.

In one embodiment, the processing unit 34 may include an executable program 46 configured to read a database 48, wherein the database 48 includes a signal specification for various types of male connector housings 100. For instance, the database 48 may contain a signal specification for a male connector having fifty-six (56) male terminal blades 102 configured to transmit power to first set of electronic devices, a male connector having fifty-six (56) male terminal blades configured to transmit power to second set of electronic devices, a male connector having forty-eight (48) male terminal blades configured to transmit power to third set of electronic devices, a male connector having forty-eight (48) male terminal blades configured to transmit power to fourth set of electronic devices, etc.

In such a case, it should be appreciated that the user may select from any one of the male connector housings 100 for testing. The database 48 may be programmable so as to add new male connector housings 100, or delete male connector housings 100 no longer in service. Accordingly, the instrument 10 may be used to test numerous male connector housings 100, subject to physical constraints as discussed in more detail below.

With reference now to FIGS. 4A and 4B a description of the operation of the instrument 10 is provided. The instrument 10 is configured to test a male connector 100 by determining the signals transmitted between an electrical connection formed by the coupling of a male terminal blade 102 with a biasing contact 24. For illustrative purposes, the instrument 10 is shown having fifty-six (56) terminal cavities 20, with fifty-six (56) wires 16 coupled to the processing unit 34. The male connector 100 is shown as having fifty-six (56) male terminal blades 102.

However, it should be appreciated that the instrument 10 may be configured to have more terminal cavities 20 than what is shown, and thus may test male connector housings 100 having different number of male terminal blades 102 other than what is shown, so long as the male terminal blades 102 are arranged to be seated as a single unit in corresponding terminal cavities 20. This may be done by programming the database 48 and the executable program 46 to read only instances where a biasing contact 24 and a male terminal blade 102 are designed to form an electric connection. For instance, the instrument 10 shown in FIGS. 3-5 may be programmed to test male connector housings 100 having any number of male terminal blades 102 less than fifty-six (56) such as a male connector 100 having 46 male terminal blades 102, so long as the male terminals blades are arranged to seat within a corresponding terminal cavity 20 as a single unit—that is when the male connector 100 is inserted into the instrument 10. In such an instance, the user selects the corresponding male connector 100 from the database 48 and, if available the corresponding set of electronic devices the male connector 100 is configured to transmit power to.

The instrument 10 is powered and the processing unit 34 processes signals from each of the electric connections. As shown in FIG. 4, the electric connection is provided by the contact of the male terminal blades 102 with a corresponding biasing contact 24. FIG. 4A shows the biasing contacts 24 in the first position 200. FIG. 4B shows how the instrument 10 accommodates manufacturing tolerances in the male connector. In particular, male terminal blade 102a is bent and is shown impacting a peripheral edge of the head 28 of the biasing contact 24a. FIGS. 4A and 4B show male terminal blade 102b being offset from the center of the terminal cavity, such an occurrence may be due to manufacturing tolerances, and also causes male terminal blade 102b to impact a peripheral edge of the head 28 of the biasing contact 24b. Furthermore, FIGS. 4A and 4B show male terminal blade 102c being shorter than male terminal blades 102a and 102b but still maintaining the same contact with the biasing contact 24c, as the other male terminal blades 102a, 102b. Accordingly, the biasing contacts 24 provide more tolerance in manufacturing and deformation in the male terminal blades. In particular, FIG. 4B shows how the head 28 gives way to a misaligned male terminal blade 102. Accordingly, the biasing contact 24 eliminates a faulty reading caused by the deformation of the female connector.

FIG. 4B also shows how the biasing contact 24 is depressed by the displacement of the male terminal blade 102. As stated above, the biasing contact 24 is continuously urged to the first position 200 so as to maintain a contact pressured engagement with the distal end of the male terminal blade 102. The biasing contact 24 will not lose its resiliency during contact engagement with the male terminal blades 102 relative to instruments utilizing female connectors with spaced apart prongs which deform and lose their resiliency.

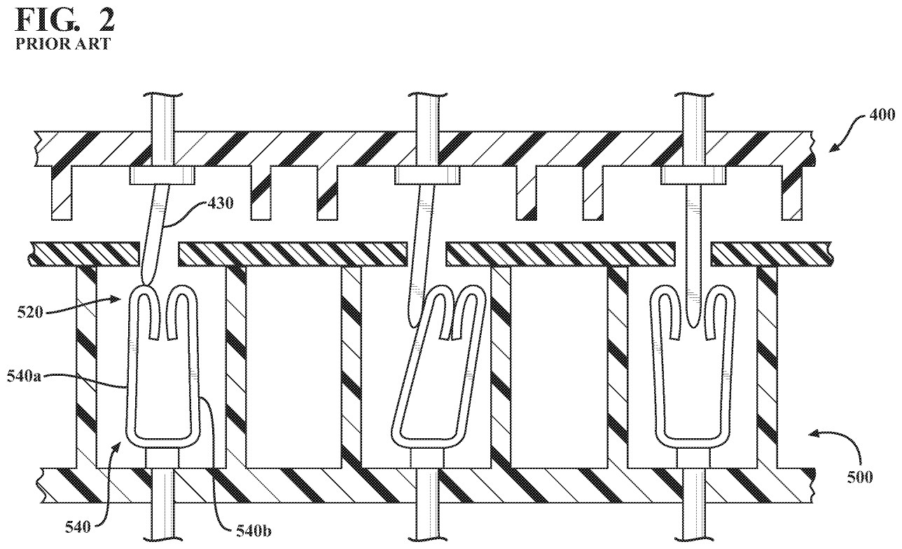

The instrument 10 reads the electric signal of each of the electrical connections. In the instant case, the instrument 10 is configured to read a signal base 26 upon the contact between a distal end of the male terminal blade 102 and a biasing contact 24 which is urged upwardly against the male terminal blade 102. Accordingly, a faulty reading is not due to an improper/insufficient contact of the female connectors due to wear or deformation common to conventional instruments. For instance, biasing contacts 24 will generate a signal by contact with the terminal blade relative to a conventional female connector with prongs which have become open as a result of repeated testing, wherein the terminal blade does not touch the prongs as shown in FIG. 2.

Thus, the head 28 is configured to engage a distal end of the male terminal blade 102 so as to provide an electric connection between the instrument 10 and the male connector 100. Further, the head 28 is configured to give way to a misaligned male terminal blade 102.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. An instrument for testing the electric connection of a second connector housing having a plurality of terminal connectors, the instrument comprising:
a first connector housing having a plurality of terminal cavities;
a plurality of biasing contacts; each of the plurality of biasing contacts are configured to move between a first position and a second position, wherein in the second position a top surface of the biasing contact is depressed relative to the first position, accordingly, the testing instrument utilizes a contact between the biasing contacts and the terminal connector of the second connector housing to test an electric connection.

2. The instrument as set forth in claim 1, wherein each of the plurality of biasing contacts includes a testing wire.

3. The instrument as set forth in claim 2, further including a processing unit, each of the testing wires are electrically coupled to the processing unit, the processing unit configured to read the electric connection between the first connector housing and the second connector housing.

4. The instrument as set forth in claim 1, wherein each of the plurality of biasing contacts includes a base and a head, the head configured to be axially displaced relative to the base.

5. The instrument as set forth in claim 4, wherein each of the plurality of biasing contacts includes a biasing member.

6. The instrument as set forth in claim 5, wherein the first connector housing includes a board having a plurality of terminal cavities, each of the plurality of biasing contacts axially aligned to a respective one of the plurality of terminal cavities.

7. The instrument as set forth in claim 6, wherein each of the plurality of biasing contacts includes a biasing member housed within the base, the biasing member configured to urge the head into the first position.

8. The instrument as set forth in claim 7, wherein the biasing member is a helical spring.

9. The instrument as set forth in claim 4, wherein the head includes a plurality of teeth spaced apart from each other so as to receive a distal edge of the male terminal blade between adjacent teeth.

10. The instrument as set forth in claim 3, wherein the processing unit includes an executable program configured to read a database, wherein the database includes a signal specification for a plurality of male connector housings, each of the plurality of male connector housings being different from each other.

11. An instrument for testing the electric connection of a male terminal connector having a plurality of male terminal blades, the instrument comprising:
a female connector housing having a female board with a plurality of terminal cavities;
a processing unit; and
a plurality of biasing contacts disposed beneath and axially aligned to a respective terminal cavity, each of the plurality of biasing contacts includes a testing wire, each of the testing wires is electrically coupled to the processing unit, the processing unit configured to read the electric connection between the male connector housing and the female connector housing, the plurality of biasing contacts is configured to move between a first position and a second position, wherein in the second position a top surface of the plurality of biasing contacts is depressed relative to the first position.

12. The instrument as set forth in claim 11, wherein each of the plurality of biasing contacts includes a base and a head, the head configured to be axially displaced relative to the base.

13. The instrument as set forth in claim 12, wherein each of the plurality of biasing contacts includes a biasing member housed within the base, the biasing member configured to urge the head into the first position.

14. The instrument as set forth in claim 13, wherein the biasing member is a helical spring.

15. The instrument as set forth in claim 11, wherein the processing unit includes an executable program configured to read a database, wherein the database includes a signal specification for a plurality of male connector housings, each of the plurality of male connector housings being different from each other.

16. An instrument for testing the electric connection of a terminal connector having a plurality of terminal blades, the instrument comprising:
a connector housing having a board with a plurality of terminal cavities; and
a plurality of biasing contacts, each of the plurality of biasing contacts are disposed beneath and axially aligned to a respective terminal cavity, the plurality of biasing contacts is configured to move between a first position and a second position, wherein in the second position a top surface of the plurality of biasing contacts is depressed relative to the first position.

17. The instrument as set forth in claim 16, wherein each of the plurality of biasing contacts includes a testing wire.

18. The instrument as set forth in claim 17, further including a processing unit, each of the testing wires are electrically coupled to the processing unit, the processing unit configured to read the electric connection between the male connector housing and the connector housing.

19. The instrument as set forth in claim 16, wherein each of the plurality of biasing contacts includes a base and a head, the head configured to be axially displaced relative to the base.

20. The instrument as set forth in claim 16, wherein each of the plurality of biasing contacts includes a biasing member.
